(19) United States
(12) Patent Application Publication
(10) Pub. No.: US 2026/0271798 A1
(43) Pub. Date: Sep. 10, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Mingyu Kim, Suwon-si (KR); Jinwoo Han, Suwon-si (KR)

(21) Appl. No.: 19/551,802

(22) Filed: Feb. 27, 2026

(30) Foreign Application Priority Data
Mar. 6, 2025 (KR) 10-2025-0029208

(51) Int. Cl. H10W 90/20; H10B 80/00; H10D 80/30; H10W 20/20; H10W 20/41; H10W 74/10; H10W 90/00; H10B 12/00; H10D 30/60; H10D 30/63; H10W 80/00

(52) U.S. Cl. CPC H10W 90/297; H10B 80/00; H10D 80/30; H10W 20/2134; H10W 20/435; H10W 74/137; H10W 90/792; H10B 12/33; H10D 30/611; H10D 30/63; H10W 80/327

(57) ABSTRACT

A semiconductor device includes a memory cell structure and a peripheral circuit structure arranged on the memory cell structure. The peripheral circuit structure includes a first substrate including at least one substrate region doped with impurities, a peripheral circuit transistor arranged on the at least one substrate region, a peripheral circuit wire layer electrically connected to the peripheral circuit transistor, a passivation layer arranged on the at least one substrate region, and a trench isolation layer penetrating the at least one substrate region, and the passivation layer exposes the trench isolation layer.

### CROSS-REFERENCE TO RELATED APPLICATION

This application is based on and claims priority under 35 U.S.C. §119 to Korean Patent Application No. 10-2025-0029208, filed on Mar. 6, 2025, in the Korean Intellectual Property Office, the disclosure of which is incorporated by reference herein in its entirety.

### BACKGROUND

With the advancement of industries and increasing demands of consumers, semiconductor devices with large storage capacity and high performance are required. To improve the performance and storage capacity of semiconductor devices, semiconductor devices having stack structures of semiconductor dies have been widely used. In addition, due to the trend of downscaling in semiconductor devices, semiconductor devices with reduced sizes are in demand.

### SUMMARY

In general, the present disclosure is directed toward a semiconductor device with improved functional reliability and a method of manufacturing the semiconductor device.

According to some implementations, the present disclosure is directed to a semiconductor device that includes a memory cell structure and a peripheral circuit structure arranged on the memory cell structure, wherein the peripheral circuit structure includes a first substrate including at least one substrate region doped with impurities, a peripheral circuit transistor arranged on the at least one substrate region, a peripheral circuit wire layer electrically connected to the peripheral circuit transistor, a passivation layer arranged on the at least one substrate region, and a trench isolation layer penetrating the at least one substrate region, and the passivation layer exposes the trench isolation layer.

According to some implementations, the present disclosure is directed to a semiconductor device that includes a memory cell structure, a peripheral circuit structure arranged on the memory cell structure, and a through via electrically connecting the memory cell structure to the peripheral circuit structure, wherein the peripheral circuit structure includes a first substrate including at least one substrate region doped with impurities, a peripheral circuit transistor arranged on the at least one substrate region, a peripheral circuit wire layer electrically connected to the peripheral circuit transistor, and a passivation layer arranged on the at least one substrate region, the through via penetrates a trench isolation layer penetrating the at least one substrate region and extends in a vertical direction, and the passivation layer exposes the trench isolation layer.

According to some implementations, the present disclosure is directed to a semiconductor device that includes a memory cell structure, a peripheral circuit structure arranged on the memory cell structure, and a through via electrically connecting the memory cell structure to the peripheral circuit structure, wherein the peripheral circuit structure includes a first substrate comprising a first substrate region and a second substrate region which have different conductive types, a peripheral circuit transistor arranged on each of the first substrate region and the second substrate region, a peripheral circuit wire layer electrically connected to the peripheral circuit transistor, and a passivation layer arranged on the first substrate region, the through via penetrates a trench isolation layer penetrating the second substrate region and extends in a vertical direction, the memory cell structure includes a second substrate, a stack structure arranged on the second substrate and including a plurality of insulating layers and a plurality of conductive lines that are alternately stacked, a plurality of channel regions spaced apart from each other in a vertical direction, a gate insulating layer arranged between respective ones of the plurality of channel regions and the plurality of conductive lines, and a cell wire layer electrically connected to an uppermost conductive line among the plurality of conductive lines, and the passivation layer exposes at least a portion of the trench isolation layer and the second substrate region.

According to some implementations, the present disclosure is directed to a method of manufacturing a semiconductor device, the method including providing a structure, on which peripheral circuit transistors, source/drain regions, a trench isolation layer, a first peripheral circuit insulating layer, and an interlayer insulating layer are formed, on a first substrate including a second substrate region and a first substrate region covering the second substrate region, exposing the second substrate region and the trench isolation layer by removing a portion of the first substrate region, forming a passivation layer on the first substrate region, and attaching a memory cell structure to the structure on which the passivation layer is formed.

According to some implementations, the forming of the passivation layer includes forming the passivation layer covering the first substrate region and the second substrate region, forming, on the passivation layer, a photoresist pattern exposing portions of the passivation layer that are arranged on the second substrate region and the trench isolation layer, and removing the portions of the passivation layer exposed by the photoresist pattern.

According to some implementations, the passivation layer may entirely cover a surface of the first substrate region.

According to some implementations, the passivation layer may entirely cover a surface of the first substrate region and may cover a portion of the second substrate region that is adjacent to the first substrate region.

According to some implementations, the passivation layer may cover a portion of the surface of the first substrate region.

According to some implementations, the forming of the passivation layer may include forming an insulating material layer on the first substrate, forming, on the insulating material layer, a photoresist pattern exposing a portion of the insulating material layer that is arranged on the first substrate region, forming an insulating pattern exposing the first substrate region after removing the portion of the insulating material layer that is exposed by the photoresist pattern, forming a passivation layer covering the insulating pattern and the first substrate region exposed by the insulating pattern; forming an insulating layer covering the passivation layer, and removing a portion of the passivation layer that covers the insulating pattern.

According to some implementations, the method may further include forming an intermediate insulating layer before the forming of the passivation layer.

According to some implementations, the attaching of the memory cell structure to the structure on which the passivation layer is formed may be performed through bonding coupling between bonding insulating layers.

According to some implementations, the attaching of the memory cell structure to the structure on which the passivation layer is formed may be performed bonding coupling between bonding pads.

According to some implementations, the method may further include forming a through via electrically connecting the memory cell structure to the peripheral circuit structure.

### BRIEF DESCRIPTION OF THE DRAWINGS

Example implementations will be more clearly understood from the following detailed description, taken in conjunction with the accompanying drawings.

FIG. 1A is a cross-sectional view of an example of a semiconductor device according to some implementations.

FIG. 1B is an enlarged cross-sectional view of an example region EX1 of FIG. 1A according to some implementations

FIG. 2 is an enlarged cross-sectional view of an example of a region corresponding to region EX1 of FIG. 1A according to some implementations.

FIG. 3 is an enlarged cross-sectional view of an example of a region corresponding to region EX1 of FIG. 1A according to some implementations.

FIG. 4A is a cross-sectional view of an example of a semiconductor device according to some implementations.

FIG. 4B is an enlarged cross-sectional view of an example of a region EX2 of FIG. 4A according to some implementations.

FIG. 5A is a cross-sectional view of an example of a semiconductor device according to some implementations.

FIG. 5B is an enlarged cross-sectional view of an example of a region EX3 of FIG. 5A according to some implementations.

FIG. 6A is a cross-sectional view of an example of a semiconductor device according to some implementations.

FIG. 6B is an enlarged cross-sectional view of an example of a region EX4 of FIG. 6A according to some implementations.

FIG. 7A is a cross-sectional view of an example of a semiconductor device according to some implementations.

FIG. 7B is an enlarged cross-sectional view of an example of a region EX5 of FIG. 7A according to some implementations.

FIG. 8A is a cross-sectional view of an example of a semiconductor device according to some implementations.

FIG. 8B is an enlarged cross-sectional view of an example of a region EX6 of FIG. 8A according to some implementations.

FIG. 8C is an enlarged cross-sectional view of an example of a region EX7 of FIG. 8A according to some implementations.

FIGS. 9 to 15 are cross-sectional views of an example of a method of manufacturing a semiconductor device according to some implementations

FIGS. 16 to 21 are cross-sectional views of an example of a method of manufacturing a semiconductor device according to some implementations.

### DETAILED DESCRIPTION

Hereinafter, example implementations will be described in detail with reference to the attached drawings. Like reference numerals in the drawings denote like elements, and repeated descriptions thereof are omitted.

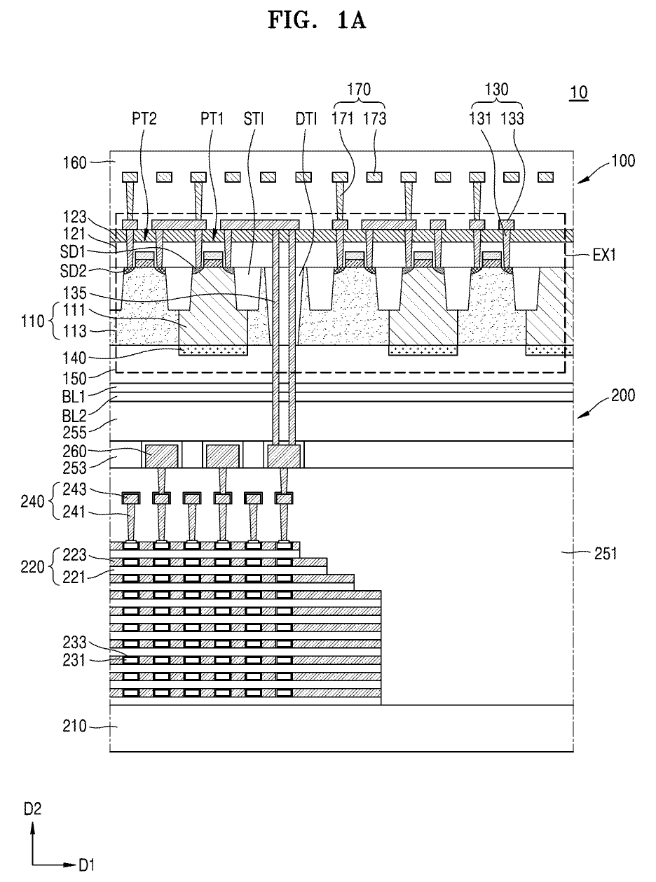

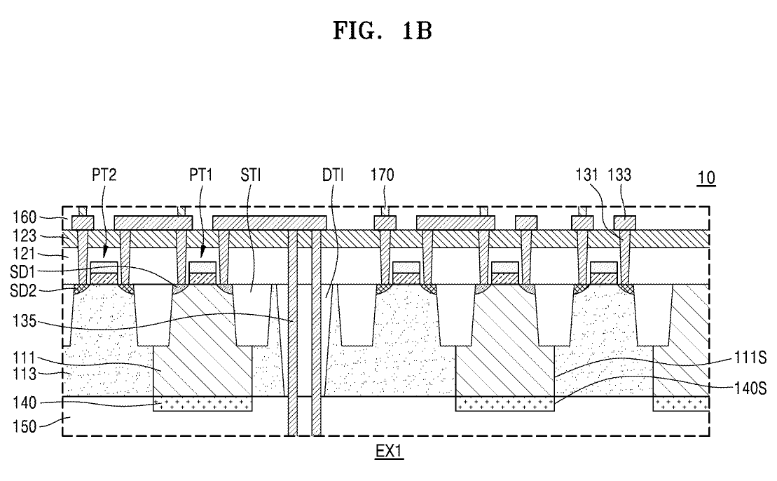

FIG. 1A is a cross-sectional view of an example of a semiconductor device 10 according to some implementations, and FIG. 1B is an enlarged cross-sectional view of an example of a region EX1 of FIG. 1A according to some implementations.

In FIGS. 1A and 1B, the semiconductor device 10 may include a peripheral circuit structure 100 and a memory cell structure 200. The peripheral circuit structure 100 may be stacked on the memory cell structure 200. The peripheral circuit structure 100 may contact the memory cell structure 200 through bonding insulating layers BL1 and BL2.

The peripheral circuit structure 100 may be a core region or a peripheral circuit region of a Dynamic Random Access Memory (DRAM) device, and the memory cell structure 200 may be an array region of a volatile memory cell of the DRAM device. For example, the peripheral circuit structure 100 may include a first peripheral circuit transistor PT1 and a second peripheral circuit transistor PT2 configured to transmit signals and/or power to memory cell transistors included in the memory cell structure 200.

The peripheral circuit structure 100 may include a first substrate 110 in which a second trench isolation layer DTI and a first trench isolation layer STI are formed. The first substrate 110 may be a wafer including silicon (Si). In some implementations, the first substrate 110 may be a wafer that includes a semiconductor element, such as germanium (Ge) or a compound semiconductor, such as silicon carbide (SiC), gallium arsenide (GaAs), indium arsenide (InAs), or indium phosphide (InP).

The first substrate 110 may include a first substrate region 111 and a second substrate region 113. The first substrate region 111 and the second substrate region 113 may be of different conductive types. For example, the first substrate region 111 may be a p-well doped with p-type impurities, and the second substrate region 113 may be an n-well doped with n-type impurities. In some implementations, the first substrate region 111 may be an n-well doped with n-type impurities, and the second substrate region 113 may be a p-well doped with p-type impurities.

A first source/drain region SD1 may be formed in the first substrate region 111, and a second source/drain region SD2 may be formed in the second substrate region 113. The first source/drain region SD1 may form a portion of the first peripheral circuit transistor PT1 described below, and the second source/drain region SD2 may form a portion of the second peripheral circuit transistor PT2 described below.

Active regions may be defined in the first substrate 110 by the second trench isolation layer DTI and the first trench isolation layer STI, which are insulating regions. The second trench isolation layer DTI may penetrate the second substrate region 113 in a vertical direction D2. The first trench isolation layer STI may extend, in the vertical direction D2, towards the inside of each of the first substrate region 111 and the second substrate region 113. As described below, through vias 135 may be arranged to penetrate the second trench isolation layer DTI. As described below, because the second trench isolation layer DTI is not covered by a passivation layer 140, the through vias 135 penetrating the second trench isolation layer DTI may not be covered by the passivation layer 140 as well. Accordingly, the through vias 135 may be spaced apart from the passivation layer 140 in a horizontal direction.

On the first substrate 110, the first peripheral circuit transistor PT1 and the second peripheral circuit transistor PT2 may be arranged. The first peripheral circuit transistor PT1 may be arranged on the first substrate region 111, and the second peripheral circuit transistor PT2 may be arranged on the second substrate region 113. In some implementations, the first peripheral circuit transistor PT1 and the second peripheral circuit transistor PT2 may each form various circuits, such as a command decoder, a control logic, an address buffer, a row decoder, a column decoder, a sense amplifier, and a data input/output circuit.

Each of the first peripheral circuit transistor PT1 and the second peripheral circuit transistor PT2 may include a gate dielectric layer and a gate electrode that are sequentially stacked in the active region. The gate dielectric layer may include at least one selected from silicon oxide (SiO₂), silicon nitride (SiNₓ), silicon oxynitride (SiON), and a high-k dielectric material having a greater dielectric constant than SiO₂. The gate electrode may include doped polysilicon, titanium nitride (TiN), titanium silicon nitride (TiSiN), tungsten (W), tungsten silicide, or a combination thereof. In some implementations, both sidewalls of the gate electrode may be covered by a gate spacer (not shown). The gate spacer may include SiO₂, SiNₓ, or a combination thereof.

Each of the first peripheral circuit transistor PT1 and the second peripheral circuit transistor PT2 may be, for example, a Gate-All Around Field Effect Transistor (GAAFET), a Multi-Bridge Channel Field Effect Transistor (MBCFET), or a Fin Field Effect Transistor (FinFET).

The first peripheral circuit insulating layer 121 may cover the first peripheral circuit transistor PT1 and the second peripheral circuit transistor PT2. An interlayer insulating layer 123 may be arranged on the first peripheral circuit insulating layer 121. The first peripheral circuit insulating layer 121 may include, for example, oxide. The interlayer insulating layer 123 may include, for example, nitride.

A first peripheral circuit wire layer 130 may be arranged on the first substrate 110. The first peripheral circuit wire layer 130 may include a first peripheral circuit via 131 and a first peripheral circuit line 133. The first peripheral circuit via 131 may penetrate the first peripheral circuit insulating layer 121 and the interlayer insulating layer 123 in the vertical direction D2. The first peripheral circuit via 131 may be in contact with the first source/drain region SD1 and the second source/drain region SD2. The first peripheral circuit via 131 may be connected to each of the first peripheral circuit transistor PT1 and the second peripheral circuit transistor PT2. The first peripheral circuit line 133 may be arranged on the interlayer insulating layer 123. The first peripheral circuit line 133 may be electrically connected to each of the first peripheral circuit transistor PT1 and the second peripheral circuit transistor PT2 through the first peripheral circuit via 131.

A second peripheral circuit wire layer 170 and a second peripheral circuit insulating layer 160 may be arranged on the interlayer insulating layer 123. The second peripheral circuit insulating layer 160 may cover the upper surface of the interlayer insulating layer 123 and the second peripheral circuit wire layer 170. The second peripheral circuit insulating layer 160 may include, for example, oxide. The second peripheral circuit wire layer 170 may include a second peripheral circuit via 171 and a second peripheral circuit line 173. The second peripheral circuit via 171 may be in contact with the first peripheral circuit line 133. The second peripheral circuit line 173 may be electrically connected to the first peripheral circuit line 133 through the second peripheral circuit via 171.

The first peripheral circuit wire layer 130 and the second peripheral circuit wire layer 170 may include, for example, a copper (Cu) layer, an aluminum (Al) layer, or a W layer.

The passivation layer 140 may be arranged on the lower surface of the first substrate region 111. The passivation layer 140 may be aligned with the first substrate region 111 in the vertical direction D2. The passivation layer 140 may cover the lower surface of the first substrate region 111. In some implementations, a side surface 140S of the passivation layer 140 may be on the same plane as a side surface 111S of the first substrate region 111. Accordingly, the entire lower surface of the first substrate region 111 may be covered by the passivation layer 140. On the contrary, the passivation layer 140 may expose the second substrate region 113. In other words, the passivation layer 140 may not cover the lower surface of the second substrate region 113. Accordingly, the lower surface of the second trench isolation layer DTI penetrating the second substrate region 113 in the vertical direction D2 may also not be covered by the passivation layer 140, thus being exposed.

In some implementations, the passivation layer 140 may include a material including fixed charges. For example, the passivation layer 140 may include aluminum oxide (Al₂O₃) or SiNₓ.

In some implementations, the conductive type of the first substrate region 111 may be different from that of the passivation layer 140. For example, when the first substrate region 111 is a p-well doped with p-type impurities, the passivation layer 140 may be a layer including negative charges. For example, the layer including negative charges may be an Al₂O₃ layer. In some implementations, when the first substrate region 111 is an n-well doped with n-type impurities, the passivation layer 140 may be a layer including positive charges. For example, the layer including positive charges may be a SiNₓ layer.

The memory cell structure 200 may include a second substrate 210. Because materials forming the second substrate 210 may be substantially the same as those forming the first substrate 110 described above, detailed descriptions thereof are omitted.

A stack structure 220 may be arranged on the second substrate 210. The stack structure 220 may include a plurality of insulating layers 221 and a plurality of conductive lines 223, which are alternately stacked. The insulating layers 221 and the conductive lines 223 may each extend in the horizontal direction D1. The insulating layers 221 and the conductive lines 223 may have lengths decreasing away from the second substrate 210 in the horizontal direction D1. Accordingly, the stack structure 220 may have a stepped structure. The conductive lines 223 may function as word lines of the memory cell structure 200.

A plurality of channel regions 231 may be spaced apart from each other in the vertical direction D2. The channel regions 231 may be spaced apart from the conductive lines 223 with gate insulating layers 233 therebetween.

A cell transistor included in the memory cell structure 200 may be, for example, a Buried Cell Array Transistor (BACT), a Vertical Cell Transistor (VCT), or a three-dimensional (3D) stacked transistor.

The uppermost conductive line 223 may be connected to a first cell wire layer 240. The first cell wire layer 240 may include a first cell via 241 and a first cell line 243. The first cell via 241 may contact the uppermost conductive line 223. In addition, the first cell via 241 may contact the lower surface of a second cell wire layer 260. The first cell line 243 may be electrically connected to the uppermost conductive line 223 through the first cell via 241. The second cell wire layer 260 may be connected to the first cell line 243 through the first cell via 241.

A first cell insulating layer 251 may cover the insulating layers 221, the conductive lines 223, and the first cell wire layer 240, and a second cell insulating layer 253 may cover the second cell wire layer 260. The first cell insulating layer 251 and the second cell insulating layer 253 may each be, for example, oxide.

The first cell wire layer 240 and the second cell wire layer 260 may include, for example, a Cu layer, an Al layer, or a W layer.

In FIG. 1A, the peripheral circuit structure 100 and the memory cell structure 200 may form a bonding structure. In some implementations, a configuration in which the peripheral circuit structure 100 is bonded onto the memory cell structure 200 may be implemented through a thermal treatment process. Here, the thermal treatment process may be performed at a temperature that is sufficient to form bonding coupling between an insulating material in the peripheral circuit structure 100 and an insulating material in the memory cell structure 200. Accordingly, the first bonding insulating layer BL1 may be bonded to the second bonding insulating layer BL2 between the peripheral circuit structure 100 and the memory cell structure 200.

The semiconductor device 10 may include the through vias 135 electrically connecting the peripheral circuit structure 100 to the memory cell structure 200. The through via 135 may penetrate, in the vertical direction D2, the interlayer insulating layer 123, the first peripheral circuit insulating layer 121, the second trench isolation layer DTI, a lower insulating layer 150, the first bonding insulating layer BL1, the second bonding insulating layer BL2, and a second upper insulating layer 255. The through via 135 may be, for example, a through silicon via. The through via 135 may electrically connect the peripheral circuit structure 100 to the memory cell structure 200. In the semiconductor device 10, two through vias 135 may be formed to penetrate the second trench isolation layer DTI and may be spaced apart from each other.

The semiconductor device 10 may include the passivation layer 140 that covers the lower surface of the first substrate region 111 and exposes the second substrate region 113 and the second trench isolation layer DTI. Because of the existence of the passivation layer 140, even if the lower insulating layer 150 has fixed charges, inversion of the conductive type of a lower part of the first substrate region 111 may be prevented, and thus, the formation of a bridge between the second substrate regions 113, which are spaced apart from each other with the first substrate region 111 therebetween, may also be prevented. In addition, because the passivation layer 140 does not cover the second trench isolation layer DTI, the formation of a bridge between two through vias 135 penetrating the second trench isolation layer DTI during the manufacturing process of the semiconductor device 10 described below - an issue that may occur when the passivation layer 140 covers the second trench isolation layer DTI - may be avoided so that the through vias 135 may not be connected. Accordingly, the functional reliability of the semiconductor device 10 may be improved.

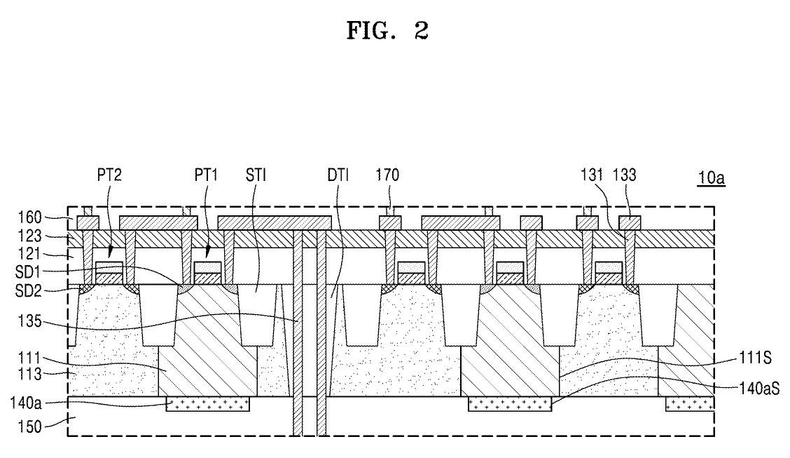

FIG. 2 is an enlarged cross-sectional view of an example of a region corresponding to region EX1 of FIG. 1A according to some implementations. Because respective components of the semiconductor device 10a of FIG. 2 are similar to those of the semiconductor device 100 described above with reference to FIGS. 1A and 1B, the differences therebetween are mainly described.

In FIG. 2, the semiconductor device 10a may have substantially the same configuration as the semiconductor device 10 shown in FIGS. 1A and 1B, except that the semiconductor device 10a includes a passivation layer 140a having side surfaces 140aS positioned more inward than side surfaces 111S of the first substrate region 111.

The side surfaces 140aS of the passivation layer 140a of the semiconductor device 10a may be positioned more inward than the side surfaces 111S of the first substrate region 111. In other words, the passivation layer 140a may cover the lower surface of the first substrate region 111, and edge portions of the lower surface of the first substrate region 111 may not be covered by the passivation layer 140a and be exposed. The exposed edge portions of the lower surface of the first substrate region 111 may be covered by the lower insulating layer 150.

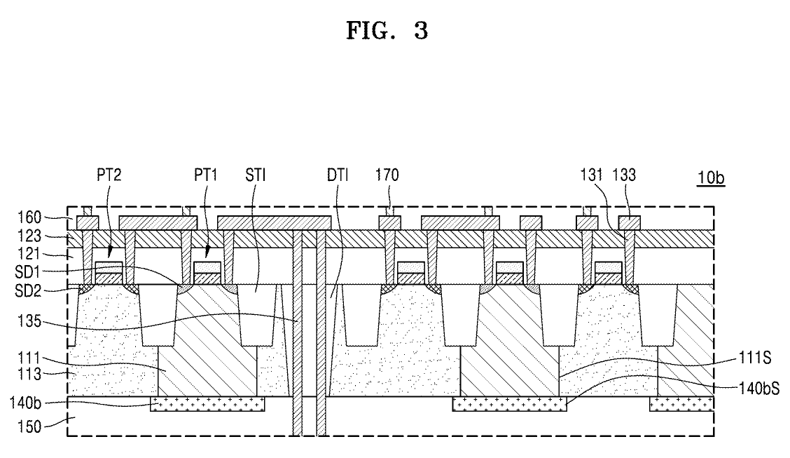

FIG. 3 is an enlarged cross-sectional view of an example of a region corresponding to region EX1 of FIG. 1A according to some implementations. Because respective components of a semiconductor device 10b of FIG. 3 are similar to those of the semiconductor device 100 described above with reference to FIGS. 1A and 1B, the differences therebetween are mainly described.

In FIG. 3, the semiconductor device 10b may have substantially the same configuration as the semiconductor device 10 shown in FIGS. 1A and 1B except that the semiconductor device 10b includes a passivation layer 140b having side surfaces 140bS positioned more outward than the side surfaces 111S of the first substrate region 111.

The side surfaces 140bS of the passivation layer 140b of the semiconductor device 10b may be positioned more outward than the side surfaces 111S of the first substrate region 111. Accordingly, the passivation layer 140b may cover the entire lower surface of the first substrate region 111 and a portion of the lower surface of the second substrate region 113 that is adjacent to the first substrate region 111. In addition, the passivation layer 140b may be aligned with the first substrate region 111 and a portion of the second substrate region 113 in the vertical direction D2.

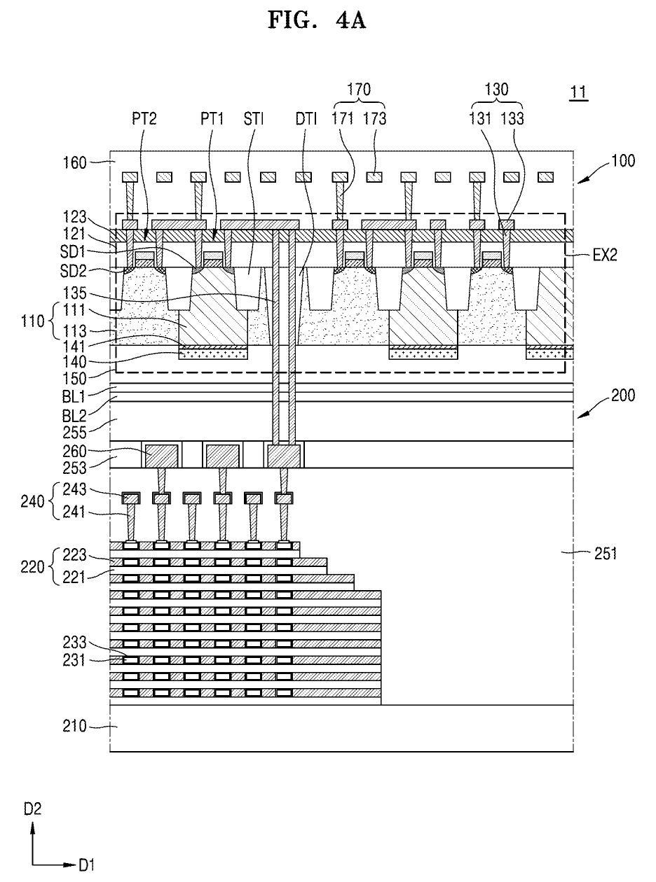

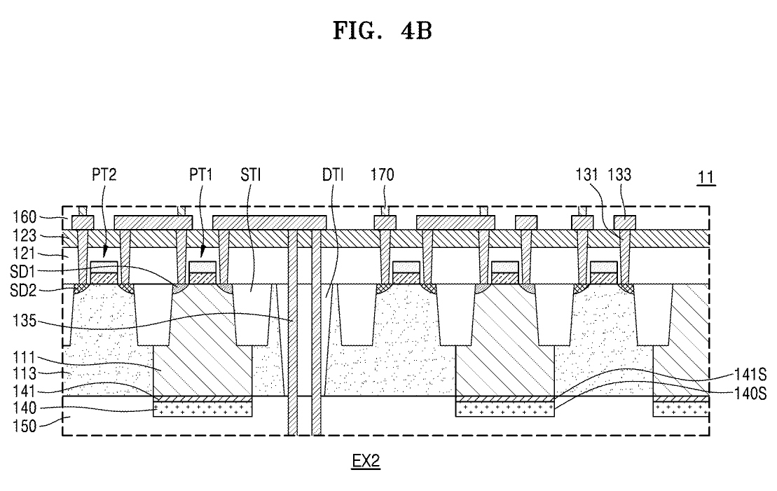

FIG. 4A is a cross-sectional view of an example of a semiconductor device 11 according to some implementations, and FIG. 4B is an enlarged cross-sectional view of an example of a region EX2 of FIG. 4A according to some implementations. Because respective components of the semiconductor device 11 of FIGS. 4A and 4B are similar to those of the semiconductor device 10 described above with reference to FIGS. 1A and 1B, the differences therebetween are mainly described.

In FIGS. 4A and 4B, the semiconductor device 11 may have substantially the same configuration as the semiconductor device 10 shown in FIGS. 1A and 1B, except that the semiconductor device 11 includes an intermediate insulating layer 141 arranged between the passivation layer 140 and the first substrate region 111.

The semiconductor device 11 may include the intermediate insulating layer 141 arranged between the passivation layer 140 and the first substrate region 111. The intermediate insulating layer 141 may cover the lower surface of the first substrate region 111. In contrast, the intermediate insulating layer 141 may not cover the lower surface of the second substrate region 113. In other words, the second substrate region 113 may be exposed by the intermediate insulating layer 141. The intermediate insulating layer 141 may be aligned with the passivation layer 140 in the vertical direction D2. The side surfaces 141S of the intermediate insulating layer 141 may be on the same plane as the side surfaces 140S of the passivation layer 140. The intermediate insulating layer 141 may be, for example, oxide. The intermediate insulating layer 141 may be included as needed, by considering the manufacturing process of the semiconductor device 11 or the electrical properties of the passivation layer 140.

FIGS. 4A and 4B illustrate that the side surfaces 140S of the passivation layer 140 and the side surfaces 141S of the intermediate insulating layer 141 are on the same plane as the side surfaces of the first substrate region 111, but some implementations may not be limited thereto. For example, unlike the configuration shown in FIGS. 4A and 4B, the side surfaces 140S of the passivation layer 140 of the semiconductor device 11 may be positioned more inward than the side surfaces of the first substrate region 111, as shown in FIG. 2, and the side surfaces 141S of the intermediate insulating layer 141 may be located on the same plane as the side surfaces 140S of the passivation layer 140 of the semiconductor device 11 and also be positioned more inward than the side surfaces of the first substrate region 111.

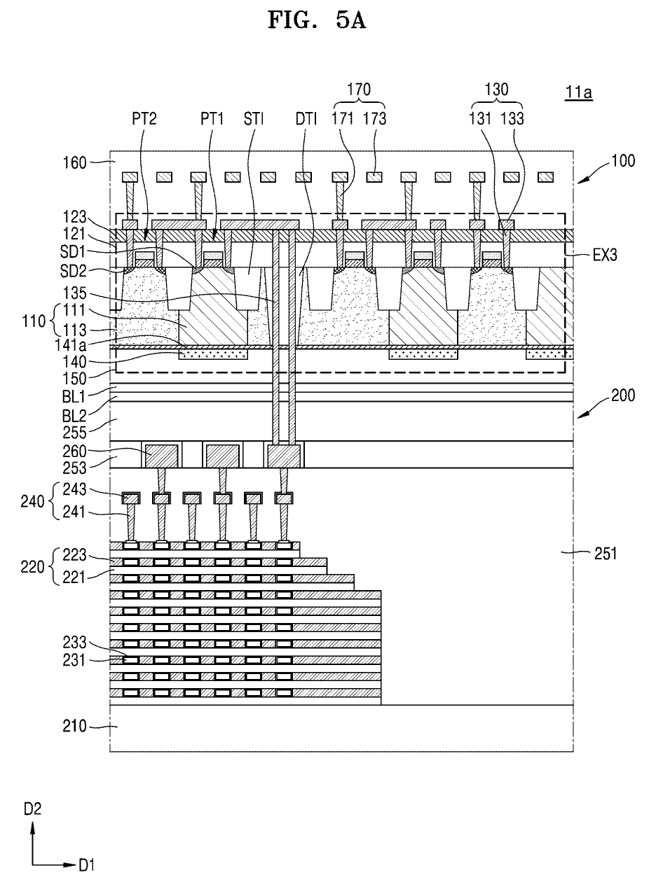

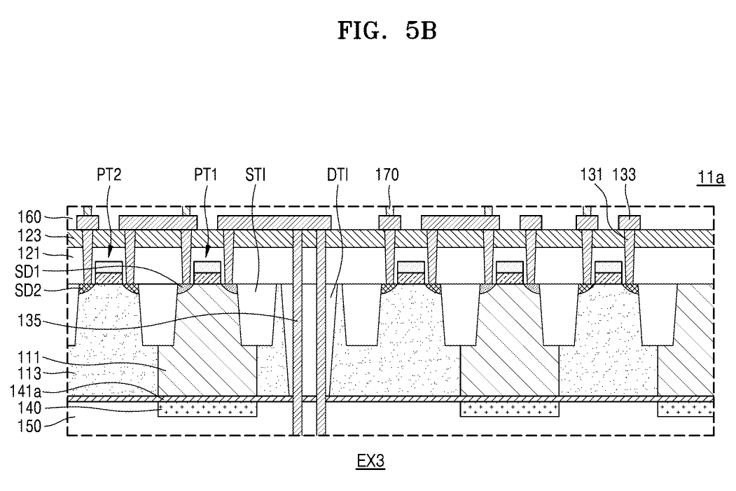

FIG. 5A is a cross-sectional view of an example of a semiconductor device 11a according to some implementations, and FIG. 5B is an enlarged cross-sectional view of an example of a region EX3 of FIG. 5A according to some implementations. Because respective components of the semiconductor device 11a of FIGS. 5A and 5B are similar to those of the semiconductor device 10 described above with reference to FIGS. 1A and 1B, the differences therebetween are mainly described.

In FIGS. 5A and 5B, the semiconductor device 11a may have substantially the same configuration as the semiconductor device 10 shown in FIGS. 1A and 1B, except that the semiconductor device 11a includes an intermediate insulating layer 141a arranged between the passivation layer 140 and the first substrate region 111.

The semiconductor device 11a may include the intermediate insulating layer 141a arranged between the passivation layer 140 and the first substrate region 111. The intermediate insulating layer 141a may extend on the lower surfaces of the first substrate region 111 and the second substrate region 113 in the horizontal direction D1. In other words, the intermediate insulating layer 141a may entirely cover the lower surfaces of the first substrate region 111 and the second substrate region 113. The intermediate insulating layer 141a may be, for example, oxide. The intermediate insulating layer 141a may be included as needed, by considering the manufacturing process of the semiconductor device 11 or the electrical properties of the passivation layer 140.

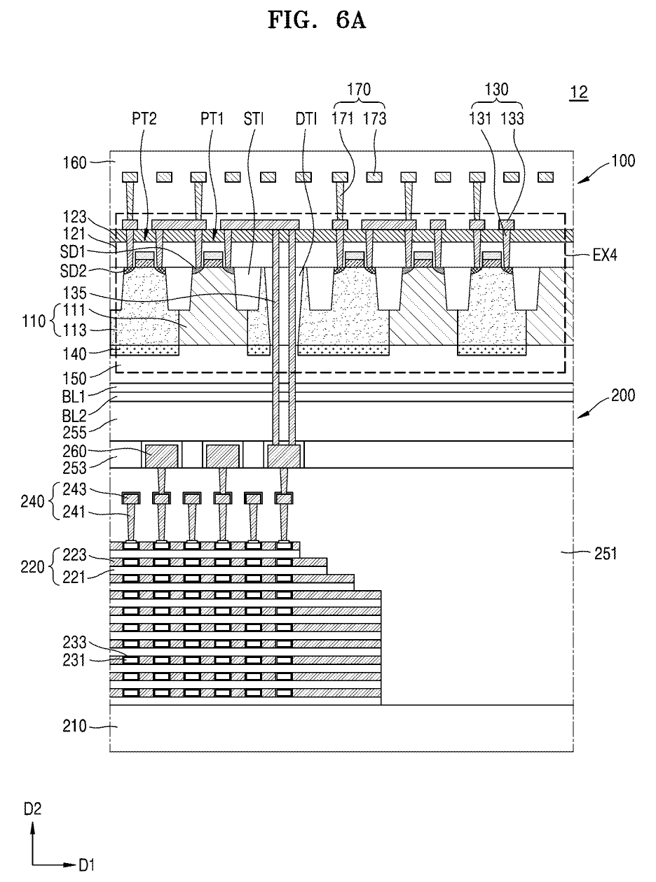

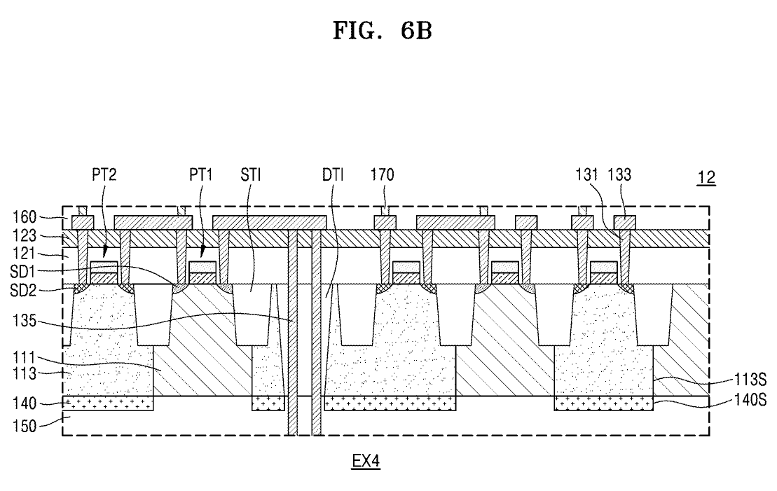

FIG. 6A is a cross-sectional view of an example of a semiconductor device 12 according to some implementations, and FIG. 6B is an enlarged cross-sectional view of an example of a region EX4 of FIG. 6A according to some implementations. Because respective components of the semiconductor device 12 of FIGS. 6A and 6B are similar to those of the semiconductor device 10 described above with reference to FIGS. 1A and 1B, the differences therebetween are mainly described.

In FIGS. 6A and 6B, the semiconductor device 12 may have substantially the same configuration as the semiconductor device 10 shown in FIGS. 1A and 1B, except that the semiconductor device 12 includes a passivation layer 140 arranged on the lower surface of the second substrate region 113.

The passivation layer 140 of the semiconductor device 12 may be arranged on the lower surface of the second substrate region 113. The passivation layer 140 may be aligned with the second substrate region 113 in the vertical direction D2. The passivation layer 140 may cover the lower surface of the second substrate region 113. In contrast, the passivation layer 140 may expose the first substrate region 111. In other words, the passivation layer 140 may not cover the lower surface of the first substrate region 111. In some implementations, the passivation layer 140 may expose the lower surface of the second trench isolation layer DTI penetrating the second substrate region 113. In other words, the passivation layer 140 may not cover the lower surface of the second trench isolation layer DTI.

In some implementations, the side surface 140S of the passivation layer 140 may be on the same plane as the side surface 113S of the second substrate region 113. However, one or more embodiments are not limited thereto. Unlike the semiconductor device 12 shown in FIGS. 6A and 6B, the side surfaces 140S of the passivation layer 140 may be positioned more inward or outward than the side surfaces 113S of the second substrate region 113. However, even when the side surfaces 140S of the passivation layer 140 are positioned more outward than the side surfaces 113S of the second substrate region 113, the passivation layer 140 may not cover the lower surface of the second trench isolation layer DTI.

In some implementations, an intermediate insulating layer may be arranged between the passivation layer 140 and the second substrate region 113. The intermediate insulating layer may be substantially the same as or similar to the intermediate insulating layer 141 of the semiconductor device 11 shown in FIGS. 4A and 4B. In some implementations, the intermediate insulating layer may be substantially the same as or similar to the intermediate insulating layer 141a of the semiconductor device 11a shown in FIGS. 5A and 5B.

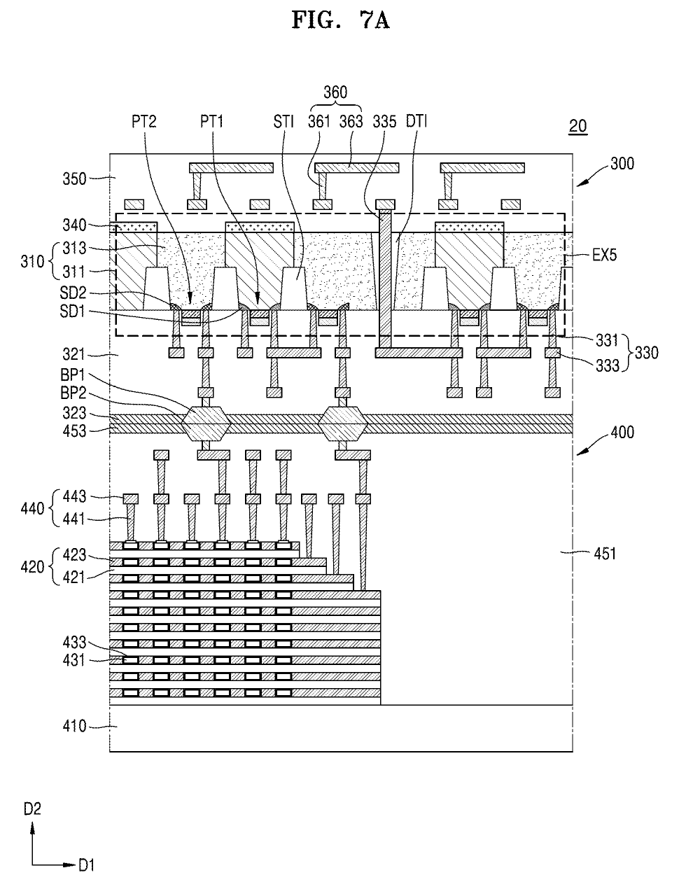

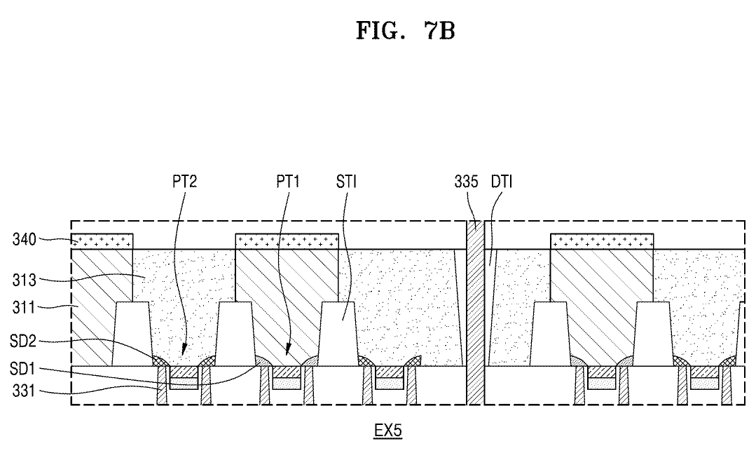

FIG. 7A is a cross-sectional view of an example of a semiconductor device 20 according to some implementations, and FIG. 7B is an enlarged cross-sectional view of an example of a region EX5 of FIG. 7A according to some implementations.

IN FIGS. 7A and 7B, the semiconductor device 20 may include a peripheral circuit structure 300 and a memory cell structure 400. The peripheral circuit structure 300 may be stacked on the memory cell structure 400. The peripheral circuit structure 300 may contact the memory cell structure 400 through bonding pads BP1 and BP2.

The peripheral circuit structure 300 may be a core region or a peripheral circuit region of a DRAM device, and the memory cell structure 400 may be an array region of a volatile memory cell of the DRAM device. For example, the peripheral circuit structure 300 may include a first peripheral circuit transistor PT1 and a second peripheral circuit transistor PT2 configured to transmit signals and/or power to memory cell transistors included in the memory cell structure 400.

The peripheral circuit structure 300 may include a first substrate 310 in which the second trench isolation layer DTI and the first trench isolation layer STI are formed. The first substrate 310 may be a wafer including Si. In some implementations, the first substrate 310 may be a wafer that includes a semiconductor element, such as Ge, or a compound semiconductor, such as SiC, GaAs, InAs, or InP.

The first substrate 310 may include a first substrate region 311 and a second substrate region 313. The first substrate region 311 and the second substrate region 313 may be of different conductive types. For example, the first substrate region 311 may be a p-well doped with p-type impurities, and the second substrate region 313 may be an n-well doped with n-type impurities. In some implementations, the first substrate region 311 may be an n-well doped with n-type impurities, and the second substrate region 313 may be a p-well doped with p-type impurities.

A first source/drain region SD1 may be formed in the first substrate region 311, and a second source/drain region SD2 may be formed in the second substrate region 313. The first source/drain region SD1 may form a portion of the first peripheral circuit transistor PT1 described below, and the second source/drain region SD2 may form a portion of the second peripheral circuit transistor PT2 described below.

Active regions may be defined in the first substrate 310 by the second trench isolation layer DTI and the first trench isolation layer STI, which are insulating regions. The second trench isolation layer DTI may penetrate the second substrate region 313 in the vertical direction D2. The first trench isolation layer STI may extend, in the vertical direction D2, towards the inside of each of the first substrate region 311 and the second substrate region 313. As described below, through vias 335 may be arranged to penetrate the second trench isolation layer DTI.

On the lower surface of the first substrate 310, the first peripheral circuit transistor PT1 and the second peripheral circuit transistor PT2 may be arranged. The first peripheral circuit transistor PT1 may be arranged on the lower surface of the first substrate region 311, and the second peripheral circuit transistor PT2 may be arranged on the lower surface of the second substrate region 313. In some implementations, the first peripheral circuit transistor PT1 and the second peripheral circuit transistor PT2 may each form various circuits, such as a command decoder, a control logic, an address buffer, a row decoder, a column decoder, a sense amplifier, and a data input/output circuit.

Each of the first peripheral circuit transistor PT1 and the second peripheral circuit transistor PT2 may include a gate dielectric layer and a gate electrode that are sequentially stacked in the active region. The gate dielectric layer may include at least one selected from SiO₂, SiNₓ, SiON, and a high-k dielectric material having a greater dielectric constant than SiO₂. The gate electrode may include doped polysilicon, TiN, TiSiN, W, tungsten silicide, or a combination thereof. In some implementations, both sidewalls of the gate electrode may be covered by a gate spacer (not shown). The gate spacer may include silicon oxide, silicon nitride, or a combination thereof.

Each of the first peripheral circuit transistor PT1 and the second peripheral circuit transistor PT2 may be, for example, a GAAFET, an MBCFET, or a FinFET. A first peripheral circuit insulating layer 321 may cover the first peripheral circuit transistor PT1 and the second peripheral circuit transistor PT2. The first peripheral circuit insulating layer 321 may include, for example, oxide.

A first peripheral insulating layer 323 may be arranged on the lower surface of the first peripheral circuit insulating layer 321. The first peripheral insulating layer 323 may surround the first bonding pad BP1. The first peripheral insulating layer 323 may include, for example, nitride.

A first peripheral circuit wire layer 330 may be arranged on the lower surface of the first substrate 310. The first peripheral circuit wire layer 330 may include a first peripheral circuit via 331 and a first peripheral circuit line 333. The first peripheral circuit via 331 may penetrate the first peripheral circuit insulating layer 321 in the vertical direction D2. The first peripheral circuit via 331 may be in contact with the first source/drain region SD1 and the second source/drain region SD2. The first peripheral circuit via 331 may be connected to each of the first peripheral circuit transistor PT1 and the second peripheral circuit transistor PT2. The first peripheral circuit line 333 may be electrically connected to each of the first peripheral circuit transistor PT1 and the second peripheral circuit transistor PT2 through the first peripheral circuit via 331. In addition, the first peripheral circuit wire layer 330 may be electrically connected to the first bonding pad BP1.

A passivation layer 340 may be arranged on the upper surface of the first substrate region 311. The passivation layer 340 may be aligned with the first substrate region 311 in the vertical direction D2. The passivation layer 340 may cover the upper surface of the first substrate region 311. In embodiments, a side surface 140S of the passivation layer 340 may be on the same plane as a side surface of the first substrate region 311. Accordingly, the entire upper surface of the first substrate region 311 may be covered by the passivation layer 340. in contrast, the passivation layer 340 may expose the second substrate region 313. In other words, the passivation layer 340 may not cover the lower surface of the second substrate region 313.

In some implementations, the conductive type of the first substrate region 311 may be different from that of the passivation layer 340. For example, when the first substrate region 311 is a p-well doped with p-type impurities, the passivation layer 340 may be a layer including negative charges. For example, the layer including negative charges may be an Al₂O₃ layer. In some implementations, when the first substrate region 311 is an n-well doped with n-type impurities, the passivation layer 340 may be a layer including positive charges. For example, the layer including positive charges may be a SiNₓ layer.

FIGS. 7A and 7B illustrate that the side surface of the passivation layer 340 is on the same plane as the side surface of the first substrate region 311, but some implementations may not be limited thereto. For example, unlike the configuration shown in FIGS. 7A and 7B, the side surface of the passivation layer 340 of the semiconductor device 20 may be positioned more inward than the side surface of the first substrate region 311 as shown in FIG. 2.

On the upper surface of the first substrate 310, a second peripheral circuit wire layer 360 and a second peripheral circuit insulating layer 350 may be arranged. The second peripheral circuit insulating layer 350 may cover the first substrate 310, the passivation layer 340, and the second peripheral circuit wire layer 360. The second peripheral circuit insulating layer 350 may include, for example, oxide.

The second peripheral circuit wire layer 360 may include a second peripheral circuit via 361 and second peripheral circuit lines 363. The second peripheral circuit via 361 may electrically connect the second peripheral circuit lines 363. The second peripheral circuit line 363 may be electrically connected to the first peripheral circuit wire layer 330 through the through via 335 described below. The first peripheral circuit wire layer 330 and the second peripheral circuit wire layer 360 may include, for example, a Cu layer, an Al layer, or a W layer.

The through via 335 may electrically connect the first peripheral circuit wire layer 330 to the second peripheral circuit wire layer 360. The through via 335 may penetrate the second peripheral circuit insulating layer 350, the second trench isolation layer DTI, and the first peripheral circuit insulating layer 321 in the vertical direction D2. The through via 335 may be, for example, a through silicon via.

The memory cell structure 400 may include a second substrate 410. Because materials forming the second substrate 410 may be substantially the same as those forming the first substrate 310 described above, detailed descriptions thereof are omitted.

A stack structure 420 may be arranged on the second substrate 410. The stack structure 420 may include a plurality of insulating layers 421 and a plurality of conductive lines 423, which are alternately stacked. The insulating layers 421 and the conductive lines 423 may each extend in the horizontal direction D1. The insulating layers 421 and the conductive lines 423 may have lengths decreasing away from the second substrate 410 in the horizontal direction D1. Accordingly, the stack structure 420 may have a stepped structure. The conductive lines 423 may function as word lines of the memory cell structure 400.

A plurality of channel regions 431 may be spaced apart from each other in the vertical direction D2. The channel regions 431 may be spaced apart from the conductive lines 423 with a gate insulating layer 433 therebetween.

A memory cell transistor included in the memory cell structure 400 may be, for example, a BACT, a VCT, or a 3D stacked transistor.

A cell wire layer 440 may be connected to the uppermost conductive line 423. The cell wire layer 440 may include a cell via 441 and a cell line 443. The cell via 441 may contact the uppermost conductive line 423. In addition, the cell via 441 may contact the lower surface of the second bonding pad BP2. The cell line 443 may be electrically connected to the uppermost conductive line 423 through the cell via 441.

A cell insulating layer 451 may cover the insulating layers 421, the conductive lines 423, and the cell wire layer 440. The second bonding pad BP2 may be arranged on the cell insulating layer 451, and the second bonding pad BP2 may be surrounded by a second peripheral insulating layer 453.

The cell insulating layer 451 may be, for example, oxide. The second peripheral insulating layer 453 may be, for example, nitride. The cell wire layer 440 may include, for example, a Cu layer, an Al layer, or a W layer.

In the semiconductor device 20, the peripheral circuit structure 300 and the memory cell structure 400 may form a bonding structure. In some implementations, a configuration in which the peripheral circuit structure 300 is bonded onto the memory cell structure 400 may be implemented through a thermal treatment process. Here, the thermal treatment process may be performed at a temperature that is sufficient to form bonding coupling between the first bonding pad BP1 of the peripheral circuit structure 300 and the second bonding pad BP2 of the memory cell structure 400. Accordingly, the first bonding pad BP1 may be bonded to the second bonding pad BP2 between the peripheral circuit structure 300 and the memory cell structure 400. The first bonding pad BP1 and the second bonding pad BP2 may each be, for example, a Cu layer. In this case, the bonding coupling between the first bonding pad BP1 and the second bonding pad BP2 may be performed through Cu-Cu hybrid bonding.

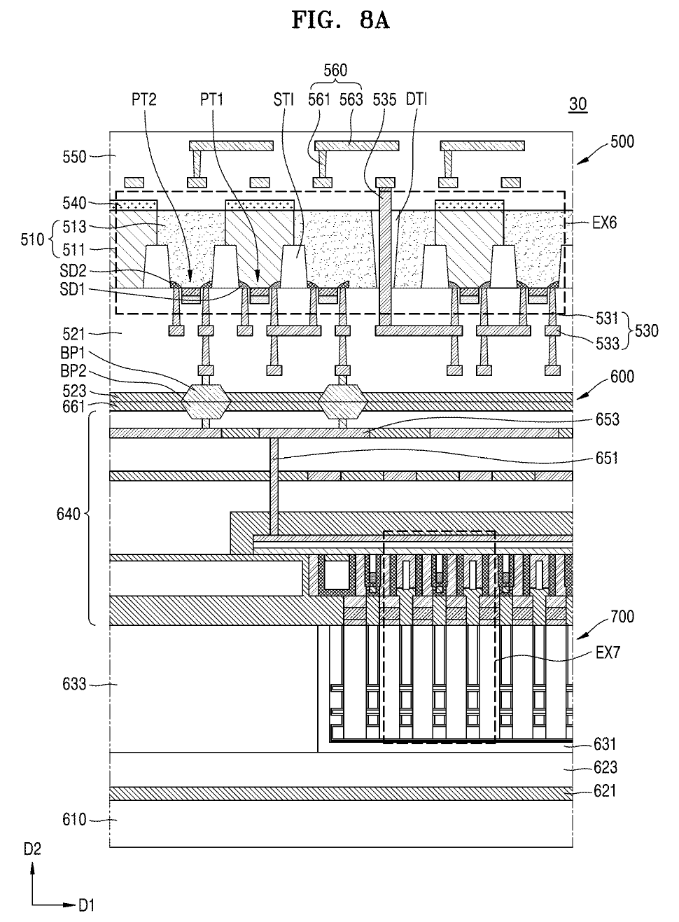

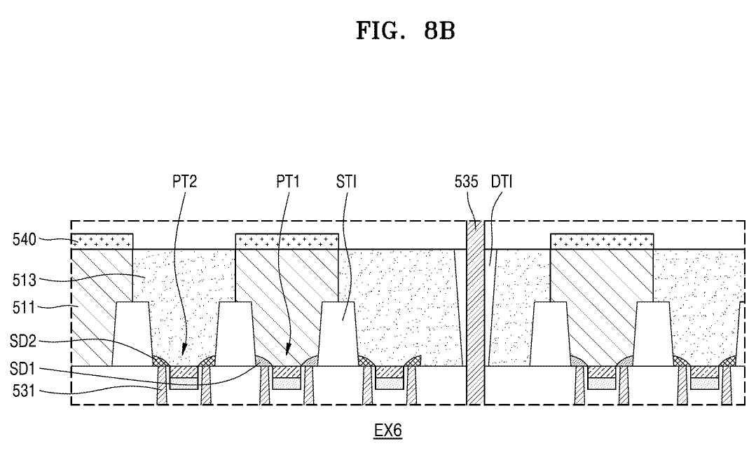

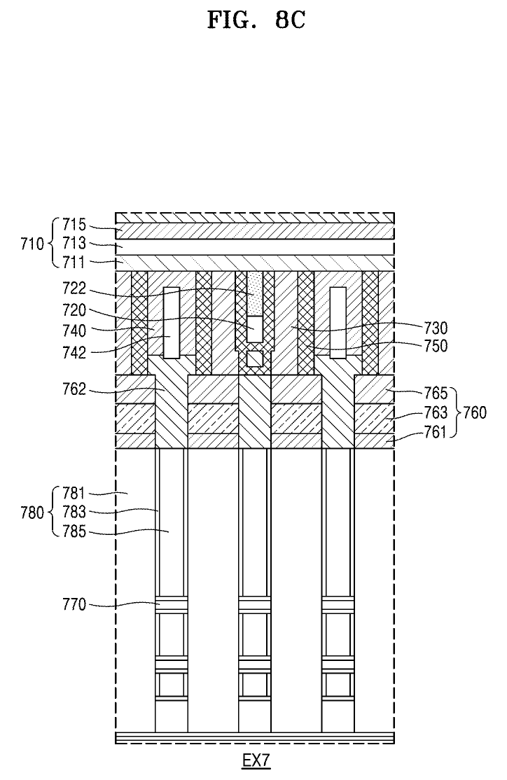

FIG. 8A is a cross-sectional view of an example of a semiconductor device 30 according to some implementations, FIG. 8B is an enlarged cross-sectional view of an example of a region EX6 of FIG. 8A according to some implementations, and FIG. 8C is an enlarged cross-sectional view of an example of a region EX7 of FIG. 8A according to some implementations.

In FIGS. 8A, 8B, 8C, the semiconductor device 30 may include a peripheral circuit structure 500 and a memory cell structure 600. The peripheral circuit structure 500 may be stacked on the memory cell structure 600. The peripheral circuit structure 500 may contact the memory cell structure 600 through the bonding pads BP1 and BP2.

The peripheral circuit structure 500 may be a core region or a peripheral circuit region of a DRAM device, and the memory cell structure 600 may be an array region of a volatile memory cell of the DRAM device. For example, the peripheral circuit structure 500 may include a first peripheral circuit transistor PT1 and a second peripheral circuit transistor PT2 configured to transmit signals and/or power to memory cell transistors included in the memory cell structure 600.

The peripheral circuit structure 500 may include a first substrate 510 in which the second trench isolation layer DTI and the first trench isolation layer STI are formed.

The first substrate 510 may be a wafer including Si. In some implementations, the first substrate 510 may be a wafer that includes a semiconductor element, such as Ge, or a compound semiconductor, such as SiC, GaAs, InAs, or InP.

The first substrate 510 may include a first substrate region 511 and a second substrate region 513. The first substrate region 511 and the second substrate region 513 may be of different conductive types. For example, the first substrate region 511 may be a p-well doped with p-type impurities, and the second substrate region 513 may be an n-well doped with n-type impurities. In some implementations, the first substrate region 511 may be an n-well doped with n-type impurities, and the second substrate region 513 may be a p-well doped with p-type impurities.

A first source/drain region SD1 may be formed in the first substrate region 511, and a second source/drain region SD2 may be formed in the second substrate region 513. The first source/drain region SD1 may form a portion of the first peripheral circuit transistor PT1 described below, and the second source/drain region SD2 may form a portion of the second peripheral circuit transistor PT2 described below.

Active regions may be defined in the first substrate 510 by the second trench isolation layer DTI and the first trench isolation layer STI, which are insulating regions. The second trench isolation layer DTI may penetrate the second substrate region 513 in the vertical direction D2. The first trench isolation layer STI may extend, in the vertical direction D2, towards the inside of each of the first substrate region 511 and the second substrate region 513. As described below, through vias 535 may be arranged to penetrate the second trench isolation layer DTI.

On the lower surface of the first substrate 510, the first peripheral circuit transistor PT1 and the second peripheral circuit transistor PT2 may be arranged. The first peripheral circuit transistor PT1 may be arranged on the lower surface of the first substrate region 511, and the second peripheral circuit transistor PT2 may be arranged on the lower surface of the second substrate region 513. In embodiments, the first peripheral circuit transistor PT1 and the second peripheral circuit transistor PT2 may each form various circuits, such as a command decoder, a control logic, an address buffer, a row decoder, a column decoder, a sense amplifier, and a data input/output circuit.

Each of the first peripheral circuit transistor PT1 and the second peripheral circuit transistor PT2 may include a gate dielectric layer and a gate electrode that are sequentially stacked in the active region. The gate dielectric layer may include at least one selected from SiO₂, SiNₓ, SiON, and a high-k dielectric material having a greater dielectric constant than SiO₂. The gate electrode may include doped polysilicon, TiN, TiSiN, W, tungsten silicide, or a combination thereof. In some implementations, both sidewalls of the gate electrode may be covered by a gate spacer (not shown). The gate spacer may include SiO₂, SiNₓ, or a combination thereof.

Each of the first peripheral circuit transistor PT1 and the second peripheral circuit transistor PT2 may be, for example, a GAAFET, an MBCFET, or a FinFET. A first peripheral circuit insulating layer 521 may cover the first peripheral circuit transistor PT1 and the second peripheral circuit transistor PT2. The first peripheral circuit insulating layer 521 may include, for example, oxide.

A first peripheral insulating layer 523 may be arranged on the lower surface of the first peripheral circuit insulating layer 521. The first peripheral insulating layer 523 may surround the first bonding pad BP1. The first peripheral insulating layer 523 may include, for example, nitride.

A first peripheral circuit wire layer 530 may be arranged on the lower surface of the first substrate 510. The first peripheral circuit wire layer 530 may include a first peripheral circuit via 531 and a first peripheral circuit line 533. The first peripheral circuit via 531 may penetrate the first peripheral circuit insulating layer 521 in the vertical direction D2. The first peripheral circuit via 531 may be in contact with the first source/drain region SD1 and the second source/drain region SD2. The first peripheral circuit via 531 may be connected to each of the first peripheral circuit transistor PT1 and the second peripheral circuit transistor PT2. The first peripheral circuit line 533 may be electrically connected to each of the first peripheral circuit transistor PT1 and the second peripheral circuit transistor PT2 through the first peripheral circuit via 531. In addition, the first peripheral circuit wire layer 530 may be electrically connected to the first bonding pad BP1.

A passivation layer 540 may be arranged on the upper surface of the first substrate region 511. The passivation layer 540 may be aligned with the first substrate region 511 in the vertical direction D2. The passivation layer 540 may cover the upper surface of the first substrate region 511. In embodiments, a side surface of the passivation layer 540 may be on the same plane as a side surface of the first substrate region 511. Accordingly, the entire upper surface of the first substrate region 511 may be covered by the passivation layer 540. In contrast, the passivation layer 540 may expose the second substrate region 513. In other words, the passivation layer 540 may not cover the lower surface of the second substrate region 513.

In some implementations, the conductive type of the first substrate region 511 may be different from that of the passivation layer 540. For example, when the first substrate region 511 is a p-well doped with p-type impurities, the passivation layer 540 may be a layer including negative charges. For example, the layer including negative charges may be an Al₂O₃ layer. In some implementations, when the first substrate region 511 is an n-well doped with n-type impurities, the passivation layer 540 may be a layer including positive charges. For example, the layer including positive charges may be a SiNₓ layer.

FIGS. 8A and 8B illustrate that the side surface of the passivation layer 540 is on the same plane as the side surface of the first substrate region 511, but some implementations may not be limited thereto. For example, unlike the configuration shown in FIGS. 8A and 8B, the side surface of the passivation layer 540 of the semiconductor device 30 may be positioned more inward than the side surface of the first substrate region 511 as shown in FIG. 2.

On the upper surface of the first substrate 510, a second peripheral circuit wire layer 560 and a second peripheral circuit insulating layer 550 may be arranged. The second peripheral circuit insulating layer 550 may cover the first substrate 510, the passivation layer 540, and the second peripheral circuit wire layer 560. The second peripheral circuit insulating layer 550 may include, for example, oxide.

The second peripheral circuit wire layer 560 may include a second peripheral circuit via 561 and second peripheral circuit lines 563. The second peripheral circuit via 561 may electrically connect the second peripheral circuit lines 563. The second peripheral circuit line 563 may be electrically connected to the first peripheral circuit wire layer 530 through the through via 535 described below. The first peripheral circuit wire layer 530 and the second peripheral circuit wire layer 560 may include, for example, a Cu layer, an Al layer, or a W layer.

The through via 535 may electrically connect the first peripheral circuit wire layer 530 to the second peripheral circuit wire layer 560. The through via 535 may penetrate the second peripheral circuit insulating layer 550, the second trench isolation layer DTI, and the first peripheral circuit insulating layer 521 in the vertical direction D2. The through via 535 may be, for example, a through silicon via.

The memory cell structure 600 may include a second substrate 610. Because materials forming the second substrate 610 may be substantially the same as those forming the first substrate 510 described above, detailed descriptions thereof are omitted.

A first lower insulating layer 621 and a second lower insulating layer 623 may be sequentially stacked on the second substrate 610. The first lower insulating layer 621 may include nitride, and the second lower insulating layer 623 may include oxide. A memory cell transistor 700 may be arranged on the second lower insulating layer 623. The memory cell transistor 700 may be surrounded by a first intermediate insulating layer 631, and the first intermediate insulating layer 631 may contact a second intermediate insulating layer 633.

The memory cell transistor 700 may include a first conductive line 710. The first conductive line 710 may extend in the horizontal direction D1. The first conductive line 710 may correspond to a bit line of the memory cell transistor 700. The first conductive line 710 may include a first lower conductive line 711, a first intermediate conductive line 713, and a first upper conductive line 715 which are sequentially stacked. The first lower conductive line 711, the first intermediate conductive line 713, and the first upper conductive line 715 may each include doped polysilicon, metal, conductive metal nitride, conductive metal silicide, conductive metal oxide, or a combination thereof.

A vertical channel layer 730 may be arranged on the lower surface of the first conductive line 710. In a plan view, the vertical channel layer 730 may be patterned in an island shape. A lower portion of the vertical channel layer 730 may function as a first source/drain region, an upper portion of the vertical channel layer 730 may function as a second source/drain region, and a portion of the vertical channel layer 730 between the first source/drain region and the second source/drain region may function as a channel region. In some implementations, the vertical channel layer 730 may include at least one of Si, Ge, and SiGe.

A gate electrode layer 740 may be arranged on one sidewall of the vertical channel layer 730, and a back gate electrode layer 720 may be arranged on the opposite sidewall of the vertical channel layer 730 that faces the one sidewall in the horizontal direction D1. The gate electrode layer 740 may correspond to a word line of the memory cell transistor 700. The gate electrode layer 740 and the back gate electrode layer 720 may include doped polysilicon, metal, conductive metal nitride, conductive metal silicide, conductive metal oxide, or a combination thereof.

Gate insulating layers 750 may be arranged between one sidewall of the vertical channel layer 730 and the gate electrode layer 740 and between the opposite sidewall of the vertical channel layer 730 and the back gate electrode layer 720. The gate insulating layer 750 may surround the sidewalls of the vertical channel layer 730. In some implementations, the gate insulating layer 750 may include SiO₂, SiON, a high-k dielectric material, or a combination thereof.

A first buried insulating layer 742 may be arranged inside the gate electrode layer 740, and a second buried insulating layer 722 may be arranged on the back gate electrode layer 720.

A capacitor contact 760 may be arranged on the lower surface of the vertical channel layer 730. The capacitor contact 760 may be aligned with the vertical channel layer 730 in the vertical direction D2 and arranged in a matrix form in a plan view. The capacitor contact 760 may include a lower contact layer 761, an intermediate contact layer 763, and an upper contact layer 765, which are sequentially stacked. An insulating layer 762 may surround the sidewalls of the capacitor contact 760.

A capacitor structure 780 may be arranged on the lower surface of the insulating layer 762. The capacitor structure 780 may include lower electrodes 781, a capacitor dielectric layer 783, and an upper electrode 785. An insulating pattern 770 may be arranged on the upper electrode 785.

An upper insulating structure 640, an upper wire via 651, and an upper wire line 653 may be arranged on the memory cell transistor 700. The upper wire via 651 and the upper wire line 653 may be referred to as an upper wire layer. The upper insulating structure 640 may cover the upper wire via 651 and the upper wire line 653. The upper insulating structure 640 may have a stack structure including insulating layers. The upper wire via 651 may extend into the upper insulating structure 640 and may contact the first conductive line 710. The upper wire line 653 may be electrically connected to the first conductive line 710 through the upper wire via 651.

The second bonding pad BP2 may be arranged on the upper insulating structure 640. The second bonding pad BP2 may be surrounded by a second peripheral insulating layer 661.

In the semiconductor device 30, the peripheral circuit structure 500 and the memory cell structure 600 may form a bonding structure. In some implementations, a configuration in which the peripheral circuit structure 500 is bonded onto the memory cell structure 600 may be implemented through a thermal treatment process. Here, the thermal treatment process may be performed at a temperature that is sufficient to form bonding coupling between the first bonding pad BP1 of the peripheral circuit structure 500 and the second bonding pad BP2 of the memory cell structure 600. Accordingly, the first bonding pad BP1 may be bonded to the second bonding pad BP2 between the peripheral circuit structure 500 and the memory cell structure 600. The first bonding pad BP1 and the second bonding pad BP2 may each be, for example, a Cu layer. In this case, bonding coupling between the first bonding pad BP1 and the second bonding pad BP2 may be performed through Cu-Cu hybrid bonding.

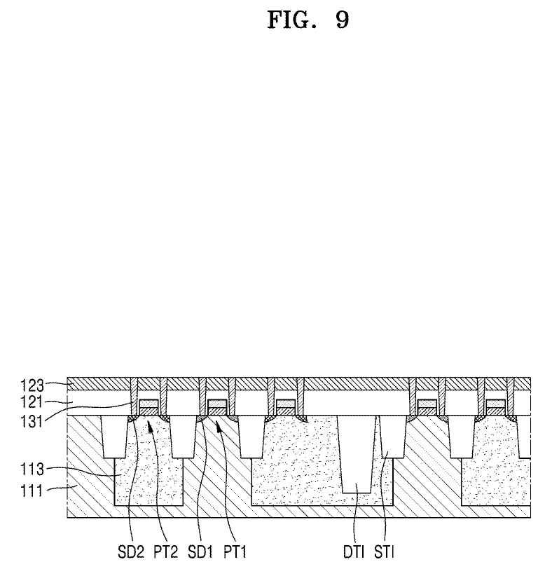

FIGS. 9 to 15 are cross-sectional views of an example of a method of manufacturing the semiconductor device 10 according to some implementations.

First, in FIG. 9, a structure including the first peripheral circuit transistor PT1, the second peripheral circuit transistor PT2, the first source/drain region SD1, the second source/drain region SD2, the first peripheral circuit insulating layer 121, and the interlayer insulating layer 123 may be provided on the first substrate 110. In FIG. 9, the first substrate 110 may include the first substrate region 111 and the second substrate region 113, and the second substrate region 113 may be covered by the first substrate region 111.

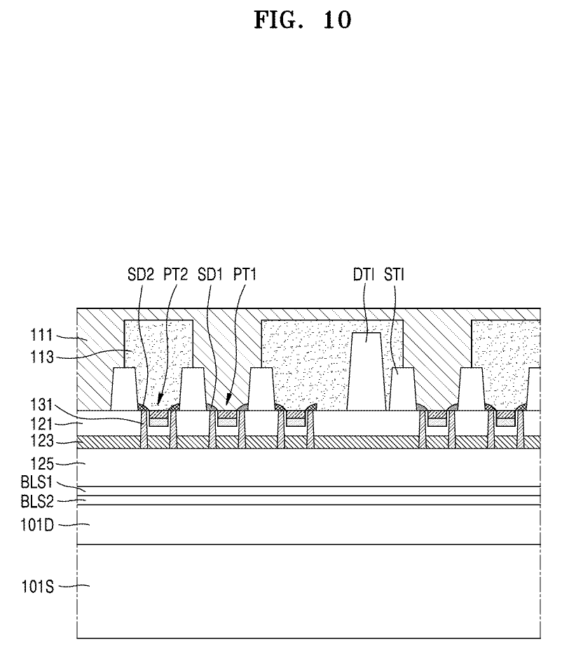

Next, in FIG. 10, a handler 101S may be attached to the result of FIG. 9, and the result of FIG. 9, to which the handler 101S is attached, may be flipped. To attach the handler 101S to the result of FIG. 9, an insulating layer 125 and a first adhesive insulating layer BLS1 may be formed on the interlayer insulating layer 123, and the handler 101S, on which a handler insulating layer 101D and a second adhesive insulating layer BLS2 are sequentially formed, may be attached to the result of FIG. 9. The attachment may be performed through bonding coupling between an insulating material forming the first adhesive insulating layer BLS1 and an insulating material forming the second adhesive insulating layer BLS2.

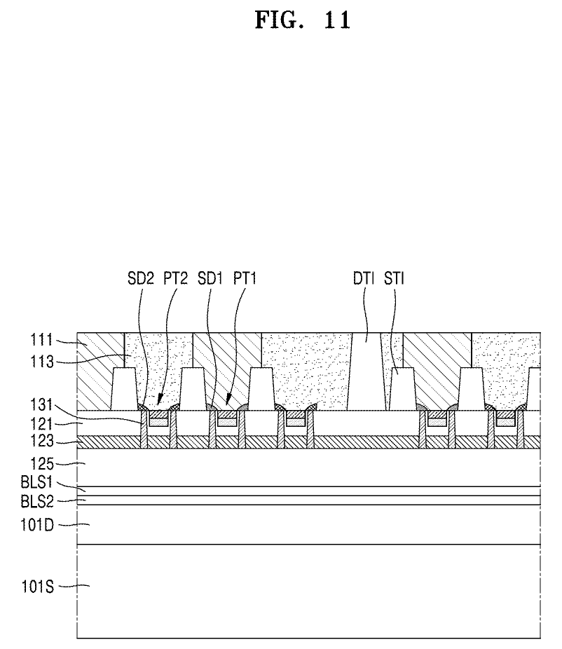

In FIG. 11, thinning may be performed on the first substrate 110 by removing a portion of the first substrate region 111 from the result of FIG. 10. As a portion of the first substrate region 111 is removed, the second substrate region 113 may be exposed.

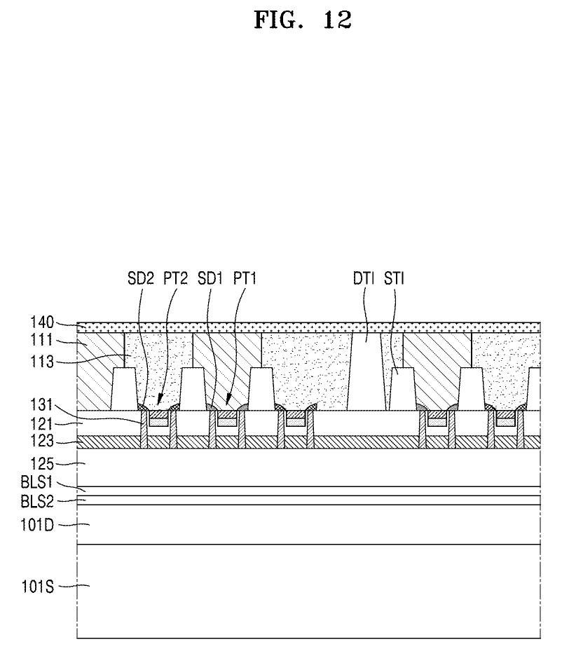

In FIG. 12, the passivation layer 140 may be formed on the first substrate 110. The passivation layer 140 may cover the first substrate 110. In some implementations, the conductive type of the first substrate region 111 may be different from that of the passivation layer 140. For example, when the first substrate region 111 is a p-well doped with p-type impurities, the passivation layer 140 may be a layer including negative charges. For example, the layer including negative charges may be an Al₂O₃ layer. In some implementations, when the first substrate region 111 is an n-well doped with n-type impurities, the passivation layer 140 may be a layer including positive charges. For example, the layer including positive charges may be a SiNₓ layer.

In some implementations, before performing the process described with reference to FIG. 12, a process of forming the intermediate insulating layer 141 on the first substrate 110 may be additionally performed. In this case, when a process described below is performed by removing a portion of the intermediate insulating layer 141, the semiconductor device 11 shown in FIGS. 4A and 4B may be manufactured, and when the process described below is performed without removing a portion of the intermediate insulating layer 141, the semiconductor device 11a shown in FIGS. 5A and 5B may be manufactured.

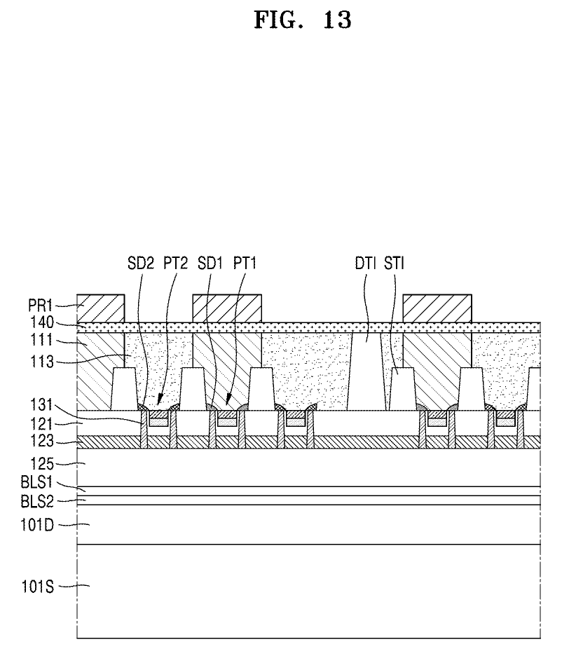

In FIG. 13, a first photoresist pattern PR1 may be formed on the passivation layer 140. The first photoresist pattern PR1 may expose a portion of the passivation layer 140 that is arranged on the second substrate region 113. On the contrary, other portions of the passivation layer 140, which are arranged on the first substrate region 111, may be covered by the first photoresist pattern PR1. FIG. 13 illustrates that the first photoresist pattern PR1 entirely exposes the portions of the passivation layer 140 arranged on the second substrate region 113 to form the passivation layer 140 as shown in FIG. 1B, but one or more embodiments are not limited thereto. For example, unlike the illustration in FIG. 13, when the entire portions of the passivation layer 140, which are arranged on the second substrate region 113, and a portion of the passivation layer 140, which is adjacent to the second substrate region 113 among the portions of the passivation layer 140 arranged on the first substrate region 111, are exposed, a passivation layer 140a shown in FIG. 2 may be formed through a process described below.

In some implementations, before the first photoresist pattern PR1 is formed on the passivation layer 140, a hard mask layer covering the passivation layer 140 may be formed. In this case, after a photoresist material layer forming the first photoresist pattern PR1 is formed on the hard mask layer, the first photoresist pattern PR1 and a hard mask pattern may be formed by removing a portion of each of the photoresist material layer and the hard mask layer. The hard mask layer may include, for example, an oxide layer. For example, the hard mask layer may include an Al₂O₃ layer.

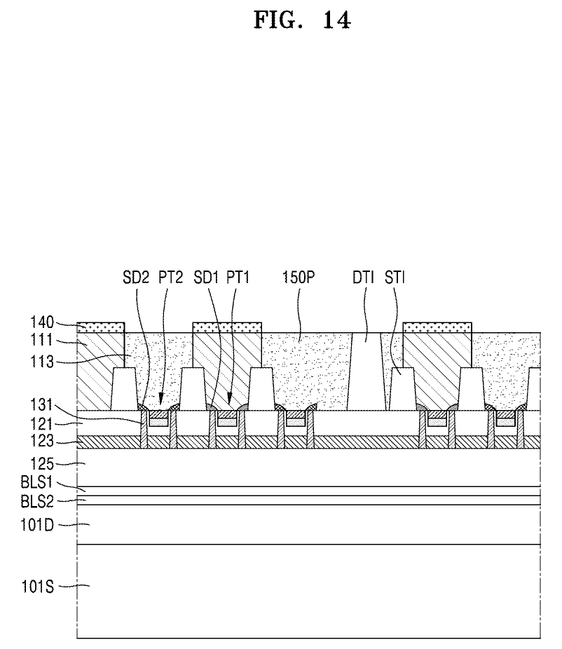

Next, in the process described below with reference to FIG. 14, portions of the passivation layer 140, which are exposed by the first photoresist pattern PR1 and the hard mask pattern, may be removed using the first photoresist pattern PR1 and the hard mask pattern.

In some implementations, unlike what is shown in FIG. 13, the first photoresist pattern PR1 may expose a portion of the passivation layer 140, which is arranged on the first substrate region 111, and a portion of the passivation layer 140, which is arranged on the second trench isolation layer DTI. In this case, when the process described below with reference to FIG. 14 is performed, the portions of the passivation layer 140, which are arranged on the first substrate region 111 and on the second trench isolation layer DTI, may be removed, and only the portions of the passivation layer 140, which are arranged on the second substrate region 113, may remain. Then, when the processes described below are performed, the semiconductor device 12 shown in FIGS. 6A and 6B may be manufactured.

In FIG. 14, a portion of the passivation layer 140 exposed by the first photoresist pattern PR1 (see FIG. 13) may be removed. Through the process shown in FIG. 14, a portion of the passivation layer 140 arranged on the second substrate region 113 may be removed, and only the portion of the passivation layer 140 arranged on the first substrate region 111 may remain. Accordingly, the second substrate region 113 and the second trench isolation layer DTI penetrating the second substrate region 113 may be exposed by the passivation layer 140.

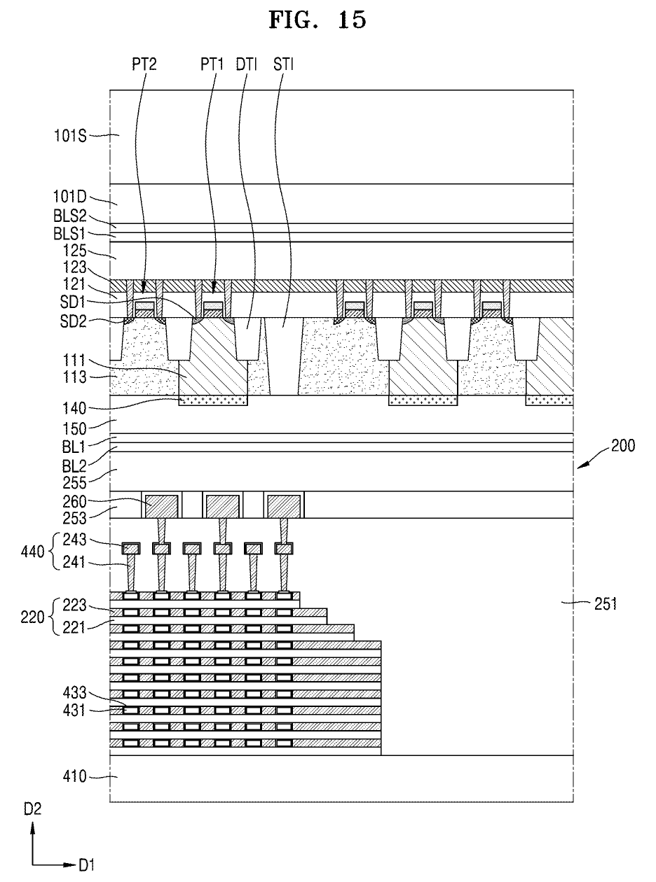

In FIG. 15, on the result of FIG. 14, the lower insulating layer 150 covering the passivation layer 140 and the first substrate 110 may be formed, and the first bonding insulating layer BL1 may be formed on the lower insulating layer 150. Next, the result, on which the lower insulating layer 150 and the first bonding insulating layer BL1 are formed, may be flipped, and the result may be attached to the memory cell structure 200 provided. The attachment may be performed through bonding coupling between an insulating material forming the first bonding insulating layer BL1 and an insulating material forming the second bonding insulating layer BL2.

Next, the handler 101S, the handler insulating layer 101D, and the second adhesive insulating layer BLS2 may be removed from the result of FIG. 15, the first peripheral circuit via 131 and the through vias 135 may be formed on the interlayer insulating layer 123, and the second peripheral circuit wire layer 170 and the second peripheral circuit insulating layer 160 may be formed; accordingly, the semiconductor device 10 shown in FIGS. 1A and 1B may be manufactured.

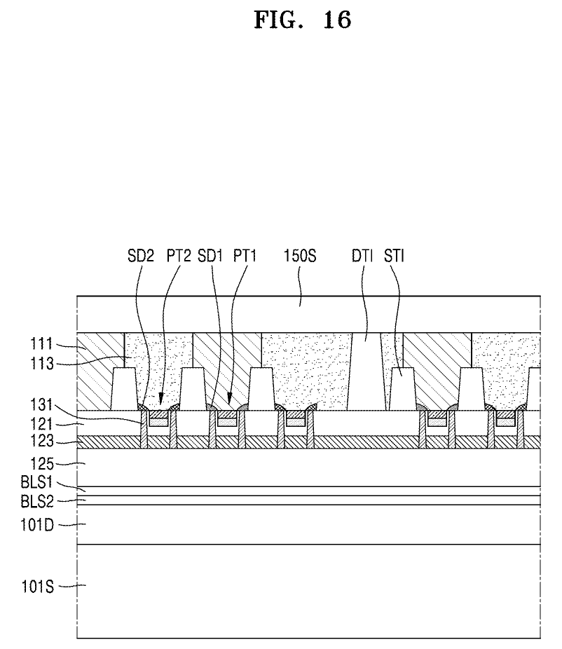

FIGS. 16 to 21 are cross-sectional views of an example of a method of manufacturing the semiconductor device 10 according to some implementations.

In FIG. 16, after the processes described with reference to FIGS. 9-11 are performed, a lower insulating material layer 150S covering the first substrate region 111 and the second substrate region 113 may be formed.

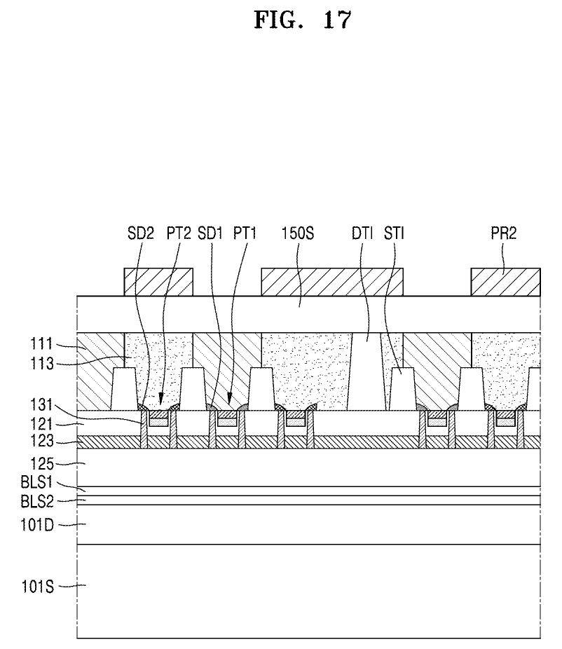

Next, in FIG. 17, the second photoresist pattern PR2 may be formed on the lower insulating material layer 150S. The second photoresist pattern PR2 may expose a portion of the lower insulating material layer 150S that is arranged on the first substrate region 111.

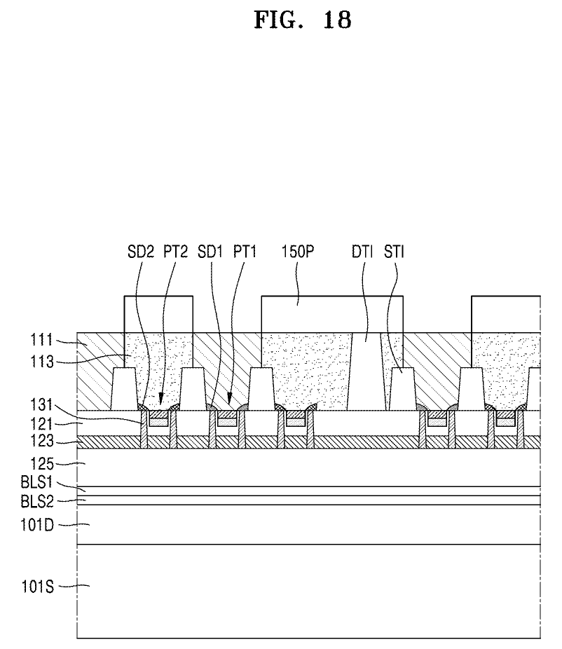

In FIG. 18, a lower insulating pattern 150P may be formed by removing a portion of the lower insulating material layer 150S that is exposed by the second photoresist pattern PR2 by using the second photoresist pattern PR2 (see FIG. 17). The upper surface of the first substrate region 111 may be exposed by the lower insulating pattern 150P. Next, the second photoresist pattern PR2 may be removed from the upper surface of the lower insulating pattern 150P.

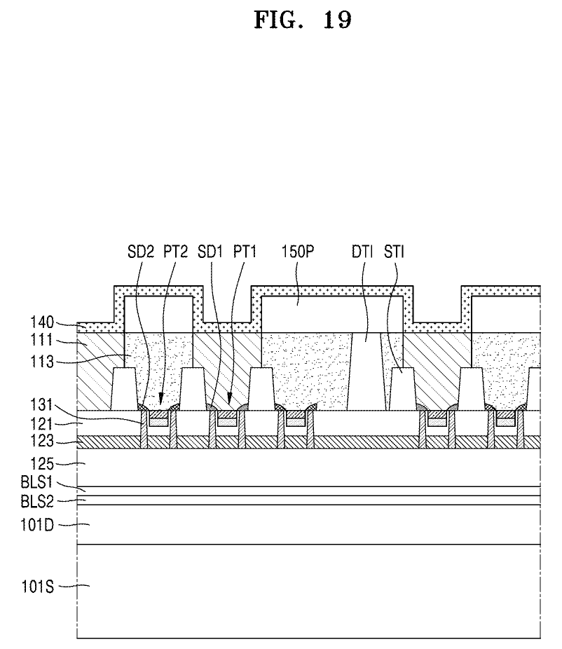

In FIG. 19, the passivation layer 140 that covers the lower insulating pattern 150P remaining after the process described with reference to FIG. 18 and the upper surface of the first substrate region 111 exposed by the lower insulating pattern 150P may be formed. The passivation layer 140 may cover the upper surface and both sidewalls of the lower insulating pattern 150P and the upper surface of the first substrate region 111.

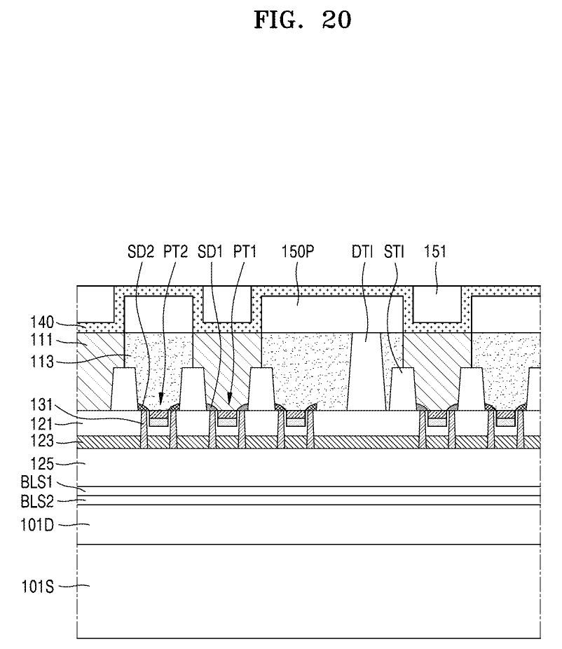

In FIG. 20, an insulating layer 151 may be formed on the passivation layer 140 and then be flattened.

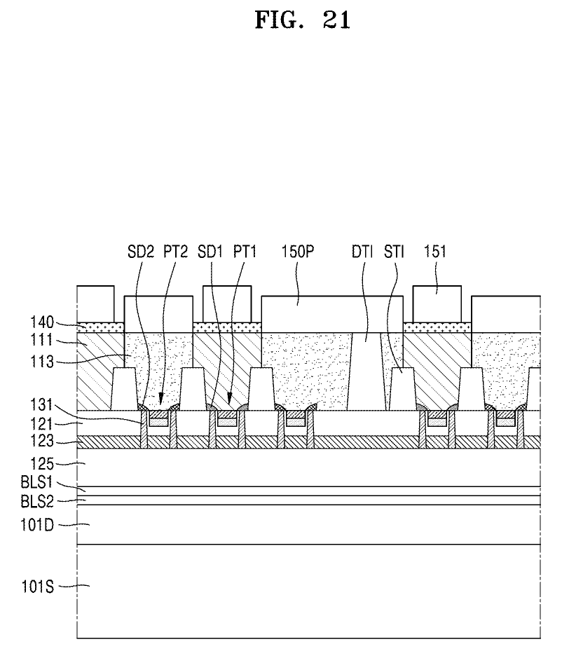

In FIG. 21, a portion of the passivation layer 140 that covers the lower insulating pattern 150P may be removed through a recess process.

Next, the lower insulating pattern 150P and the insulating layer 151 may be removed from the result of FIG. 21, and the process described with reference to FIG. 15 may be performed. Then, the handler 101S, the handler insulating layer 101D, and the second adhesive insulating layer BLS2 may be removed, the first peripheral circuit via 131 and the through vias 135 may be formed on the interlayer insulating layer 123, and the second peripheral circuit wire layer 170 and the second peripheral circuit insulating layer 160 may be formed; accordingly, the semiconductor device 10 shown in FIGS. 1A and 1B may be manufactured.

In some implementations, after performing the process described with reference to FIG. 21, a cover insulating layer covering the lower insulating pattern 150P, the insulating layer 151, and the passivation layer 140 may be formed without removing the lower insulating pattern 150P and the insulating layer 151. In this case, the lower insulating pattern 150P, the insulating layer 151, and the cover insulating layer may form the lower insulating layer 150. Next, as in the process described with reference to FIG. 15, the first bonding insulating layer BL1 may be formed on the lower insulating layer 150, the handler 101S, the handler insulating layer 101D, and the second adhesive insulating layer BLS2 may be removed, the first peripheral circuit via 131 and the through vias 135 may be formed on the interlayer insulating layer 123, and the second peripheral circuit wire layer 170 and the second peripheral circuit insulating layer 160 may be formed; accordingly, the semiconductor device 10 shown in FIGS. 1A and 1B may be manufactured.

In some implementations, a method of manufacturing a semiconductor device includes providing a structure, on which peripheral circuit transistors, source/drain regions, a trench isolation layer, a first peripheral circuit insulating layer, and an interlayer insulating layer are formed, on a first substrate including a second substrate region and a first substrate region covering the second substrate region, exposing the second substrate region and the trench isolation layer by removing a portion of the first substrate region, forming a passivation layer on the first substrate region, and attaching a memory cell structure to the structure on which the passivation layer is formed.

In some implementations, the forming of the passivation layer includes forming the passivation layer covering the first substrate region and the second substrate region, forming, on the passivation layer, a photoresist pattern exposing portions of the passivation layer that are arranged on the second substrate region and the trench isolation layer, and removing the portions of the passivation layer exposed by the photoresist pattern.

In some implementations, the passivation layer may entirely cover a surface of the first substrate region.

In some implementations, the passivation layer may entirely cover a surface of the first substrate region and may cover a portion of the second substrate region that is adjacent to the first substrate region.

In some implementations, the passivation layer may cover a portion of the surface of the first substrate region.

In some implementations, the forming of the passivation layer may include forming an insulating material layer on the first substrate, forming, on the insulating material layer, a photoresist pattern exposing a portion of the insulating material layer that is arranged on the first substrate region, forming an insulating pattern exposing the first substrate region after removing the portion of the insulating material layer that is exposed by the photoresist pattern, forming a passivation layer covering the insulating pattern and the first substrate region exposed by the insulating pattern; forming an insulating layer covering the passivation layer, and removing a portion of the passivation layer that covers the insulating pattern.

In some implementations, the method may further include forming an intermediate insulating layer before the forming of the passivation layer.

In some implementations, the attaching of the memory cell structure to the structure on which the passivation layer is formed may be performed through bonding coupling between bonding insulating layers.

In some implementations, the attaching of the memory cell structure to the structure on which the passivation layer is formed may be performed bonding coupling between bonding pads.

In some implementations, the method may further include forming a through via electrically connecting the memory cell structure to the peripheral circuit structure.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a memory cell structure; and
a peripheral circuit structure on the memory cell structure,
wherein the peripheral circuit structure comprises
a first substrate comprising at least one substrate region doped with impurities,
a peripheral circuit transistor on the at least one substrate region,
a peripheral circuit wire layer electrically connected to the peripheral circuit transistor,
a passivation layer on the at least one substrate region, and
a trench isolation layer extending into the at least one substrate region, and
wherein the passivation layer exposes the trench isolation layer.

2. The semiconductor device of claim 1, wherein the passivation layer comprises a material having fixed charges.

3. The semiconductor device of claim 1,
wherein the at least one substrate region comprises a first substrate region and a second substrate region that have different conductivity types,
wherein the passivation layer is on the first substrate region, and
wherein the trench isolation layer penetrates at least one of the first substrate region and the second substrate region.

4. The semiconductor device of claim 3, wherein a conductivity type of the passivation layer is different from the conductivity type of the first substrate region.

5. The semiconductor device of claim 3, wherein the passivation layer entirely covers a surface of the first substrate region, excluding the trench isolation layer.

6. The semiconductor device of claim 3, wherein the passivation layer entirely covers a surface of the first substrate region, excluding the trench isolation layer, and covers a portion of the second substrate region.

7. The semiconductor device of claim 3, wherein the passivation layer covers a first portion of a surface of the first substrate region, excluding the trench isolation layer, and exposes a second portion of the surface of the first substrate region.

8. The semiconductor device of claim 3, comprising an intermediate insulating layer between the first substrate region and the passivation layer.

9. The semiconductor device of claim 8, wherein the intermediate insulating layer is aligned with the passivation layer in a vertical direction.

10. The semiconductor device of claim 8, wherein the intermediate insulating layer exposes the trench isolation layer or the second substrate region, or exposes at least a portion of both the trench isolation layer and the second substrate region.

11. The semiconductor device of claim 8, wherein the intermediate insulating layer covers the first substrate region and the second substrate region.

12. The semiconductor device of claim 1, wherein the memory cell structure comprises:
a second substrate;
a stack structure on the second substrate, the stack structure comprising a plurality of insulating layers and a plurality of conductive lines that are alternately stacked;
a plurality of channel regions spaced apart from each other in a vertical direction;
a gate insulating layer between respective channel regions of the plurality of channel regions and the plurality of conductive lines; and
a cell wire layer electrically connected to an uppermost conductive line among the plurality of conductive lines.

13. The semiconductor device of claim 12, wherein the memory cell structure and the peripheral circuit structure are bonded together.

14. The semiconductor device of claim 12, wherein the memory cell structure and the peripheral circuit structure are bonded through bonding coupling between bonding pads.

15. The semiconductor device of claim 1, wherein the memory cell structure comprises:
a second substrate;
a memory cell transistor on the second substrate; and
an upper wire layer electrically connected to the memory cell transistor, and
wherein the memory cell transistor comprises
a capacitor structure,
a vertical channel layer on the capacitor structure,
a gate electrode layer on a first sidewall of the vertical channel layer, and
a back gate electrode layer arranged on a second sidewall opposite to the first sidewall of the vertical channel layer.

16. A semiconductor device comprising:
a memory cell structure;
a peripheral circuit structure on the memory cell structure; and
a through via electrically connecting the memory cell structure to the peripheral circuit structure,
wherein the peripheral circuit structure comprises
a first substrate comprising at least one substrate region doped with impurities,
a peripheral circuit transistor on the at least one substrate region,
a peripheral circuit wire layer electrically connected to the peripheral circuit transistor, and
a passivation layer on the at least one substrate region,
wherein the through via extends into a trench isolation layer, wherein the trench isolation layer extends into the at least one substrate region in a vertical direction, and
wherein the passivation layer exposes the trench isolation layer.

17. The semiconductor device of claim 16, wherein the through via is spaced apart from the passivation layer in a horizontal direction.

18. The semiconductor device of claim 16, comprising an intermediate insulating layer between the at least one substrate region and the passivation layer.

19. The semiconductor device of claim 18, wherein the intermediate insulating layer is aligned with the passivation layer in a vertical direction.

20. A semiconductor device comprising:
a memory cell structure;
a peripheral circuit structure on the memory cell structure; and
a through via electrically connecting the memory cell structure to the peripheral circuit structure,
wherein the peripheral circuit structure comprises
a first substrate comprising a first substrate region and a second substrate region that have different conductivity types,
a peripheral circuit transistor on each of the first substrate region and the second substrate region,
a peripheral circuit wire layer electrically connected to the peripheral circuit transistor, and
a passivation layer on the first substrate region,
wherein the through via extends into a trench isolation layer that extends into the second substrate region and extends in a vertical direction,
wherein the memory cell structure comprises
a second substrate,
a stack structure on the second substrate, the stack structure comprising a plurality of insulating layers and a plurality of conductive lines that are alternately stacked,
a plurality of channel regions spaced apart from each other in a vertical direction,
a gate insulating layer between respective ones of the plurality of channel regions and the plurality of conductive lines, and
a cell wire layer electrically connected to an uppermost conductive line among the plurality of conductive lines, and
wherein the passivation layer is configured to expose at least a portion of the trench isolation layer and the second substrate region.
